(19) United States
(12) Patent Application Publication
(10) Pub. No.: US 2007/0181896 A1
(43) Pub. Date: Aug. 9, 2007

(54) Structure for a single light source multicolor LED

(76) Inventor: Been-Yu Liaw, Jhongli City (TW)

Correspondence Address: Troxell Law Office Pllc, Suite 1404, 5205 Leesburg Pike, Falls Church, VA, 22041, US

(21) Appl. No.: 11/346,358

(22) Filed: Feb. 3, 2006

(51) Int. Cl. H01L 33/00

(52) U.S. Cl. 257/99

(57) ABSTRACT

A single light source multicolor LED, including a package baseplate having a high heat dissipation effect, and the package baseplate is provided with a heat dissipating layer and a printed circuit. The printed circuit includes an insulating layer, a conductive layer and a covering layer. A surface of the package baseplate is provided with a concavity, interior of which is provided with a light reflecting layer and an array of a plurality of light-emitting chips. Extended electrical contacts of the printed circuit enable the array of the plurality of light-emitting chips within the concavity to be respectively soldered to the conductive layer of the printed circuit, and varied high and low electric potential of the printed circuit produces varied electric currents that control the array of the plurality of light-emitting chips, thereby enabling the package baseplate to produce multicolor varied frequency spectral light from a single light source.

### BACKGROUND OF THE INVENTION

(a) Field of the Invention

The present invention relates to a structure for a single light source multicolor LED (light-emitting diode).

(b) Description of the Prior Art

A conventional package structure A1 of a chip A, as depicted in FIGS. 1 and 2, has an insulating layer A3 coated on a baseplate A2 of the package structure A1, and a surface of the insulating layer A3 is provided with soldering layers A4, interior of which are provided with circuit wiring. When joining the package structure A1 and the chip A, power source connecting terminals A5 extending from ends of two sides of the chip A are soldered to the soldering layers A4, thereby soldering the chip A to the soldering layers A4, and enabling an electrical connection to be made to a power source through the circuit wiring. After a power source is connected, the chip A produces a single frequency spectral light source.

However, because the insulating layer A3 is fabricated from material that is able to block electric current, thus, when the light source of the chip A is producing heat energy, the insulating layer A3 of the package structure A1 is unable to effectively dissipate heat, which easily causes reduction in the brightness and affects the serviceable life of the chip A. Moreover, regarding the problem of the point source of light being only able to emit a fixed color, the present invention provides an electric circuit control configuration to achieve the objective of complete color control, and design of a special high heat dissipation baseplate enables a plurality of light-emitting chips to be simultaneously disposed under a structure of a single light source and achieve normal operation.

Hence, the inventor of the present invention proposes to resolve and surmount existent technical difficulties to eliminate the aforementioned shortcomings of prior art.

### SUMMARY OF THE INVENTION

The present invention provides a structure for a single light source multicolor LED (light-emitting diode), which uses a conductive layer of a printed circuit so that when an array of a plurality of light-emitting chips are connected to the printed circuit, extended electrical contacts of the printed circuit enable the array of the plurality of light-emitting chips within a concavity to be respectively connected to the conductive layer of the printed circuit. Moreover, the printed circuit controls the array of the plurality of light-emitting chips within the concavity by means of varied high and low electric potential to enable a package baseplate to produce multicolor varied frequency spectral light from a single light source.

To enable a further understanding of said objectives and the technological methods of the invention herein, brief description of the drawings is provided below followed by detailed description of the preferred embodiments.

### BRIEF DESCRIPTION OF THE DRAWINGS

FIG. 1 shows an elevational view of prior art.

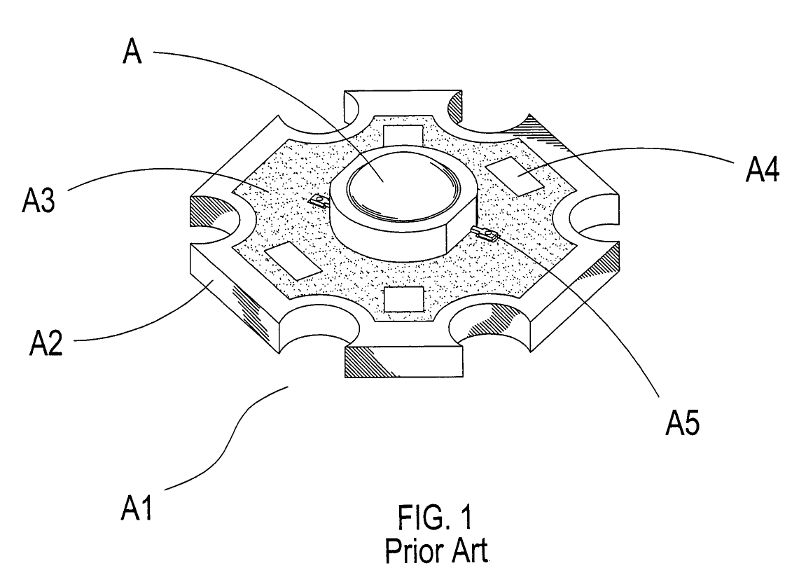

FIG. 2 shows a cutaway view of prior art.

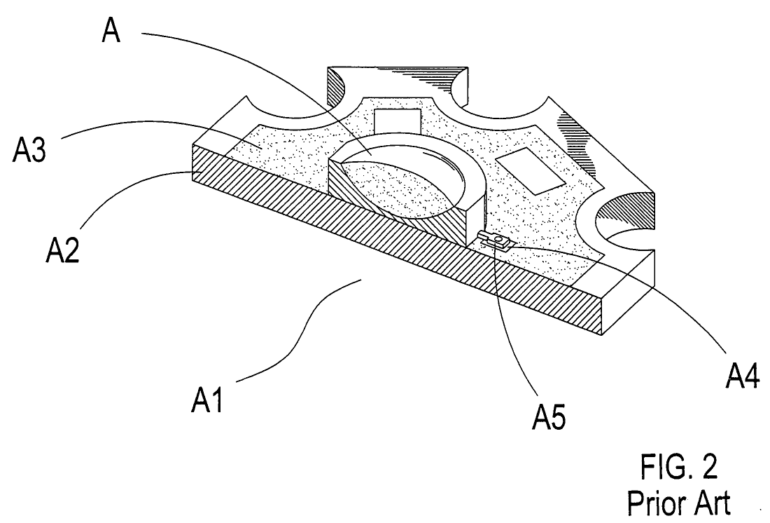

FIG. 3 shows an elevational view according to the present invention.

FIG. 4 shows a cutaway view according to the present invention.

FIG. 5 shows a schematic view according to the present invention.

FIG. 6 shows a schematic view of an embodiment according to the present invention.

### DETAILED DESCRIPTION OF THE PREFERRED EMBODIMENTS

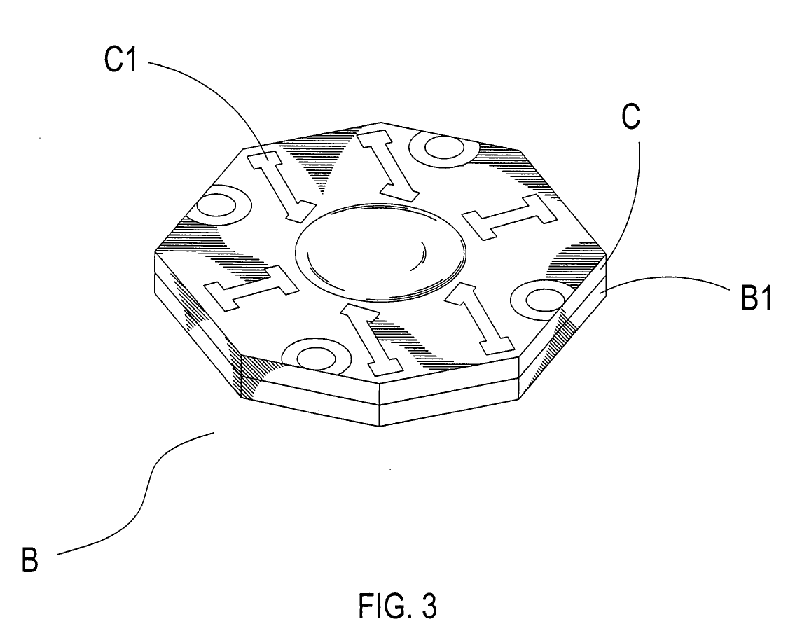

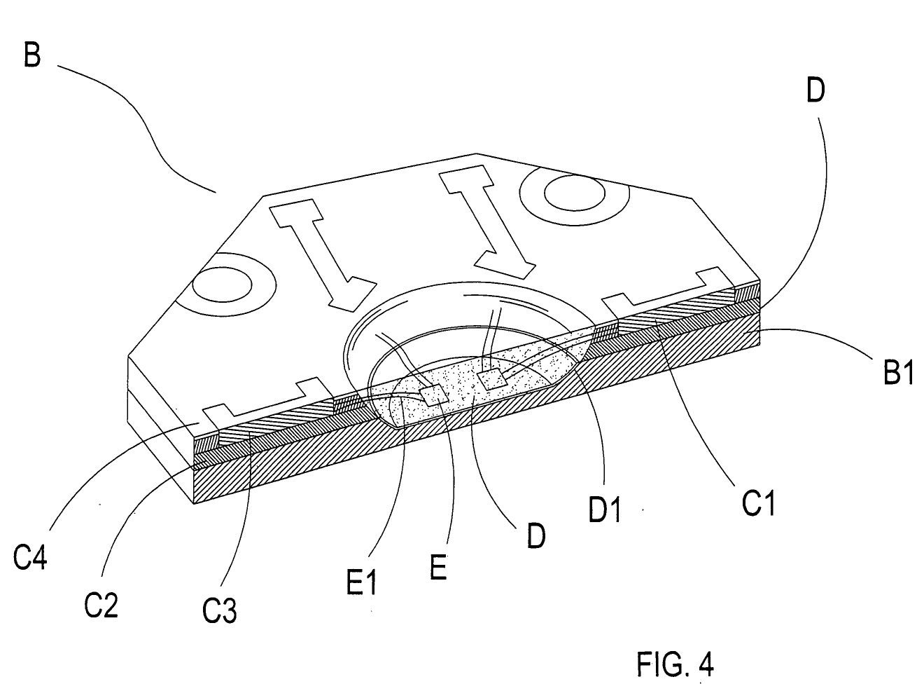

The present invention provides a structure for a single light source multicolor LED (light-emitting diode). Referring to FIGS. 3 and 4, which show the present invention comprising a package baseplate B having a high heat dissipation effect and provided with a heat dissipating layer B1 and a printed circuit C. The printed circuit C comprises electrical contacts C1, an insulating layer C2, a conductive layer C3 and a covering layer C4. Furthermore, the printed circuit C covers a surface of the heat dissipating layer B1 of the package baseplate B.

A surface of the package baseplate B is provided with a concavity D, interior of which is provided with a light reflecting layer D1. Moreover, interior of the concavity D is provided with an array of a plurality of light-emitting chips E, which are respectively connected to the electrical contacts C1 by way of power source connecting lines E1. Furthermore, the printed circuit C and the heat dissipating layer B cover the insulating layer C2, and the insulating layer C2 is covered by the conductive layer C3 and the covering layer C4.

The present invention is characterized in that when soldering the light-emitting chips E, the electrical contacts C1 of the printed circuit C enable the array of the plurality of light-emitting chips E within the concavity D to be respectively connected to the conductive layer C3 of the printed circuit C, and after electrical connection of the package baseplate B to a power source, varied high and low electric potential of the printed circuit C enable a single light source to produce multicolor varied frequency spectral light. When the array of the plurality of light-emitting chips E are dissipating heat, the heat dissipating characteristic of the bottom covering heat dissipating layer B1 of the package baseplate B is able to uniformly discharge the light heat energy produced by the varied frequency spectral colored light emitted by the light-emitting chips E from the package baseplate B, which further effectively improves brightness of the varied colored light and extends the serviceable life of the light-emitting chips E within the concavity D.

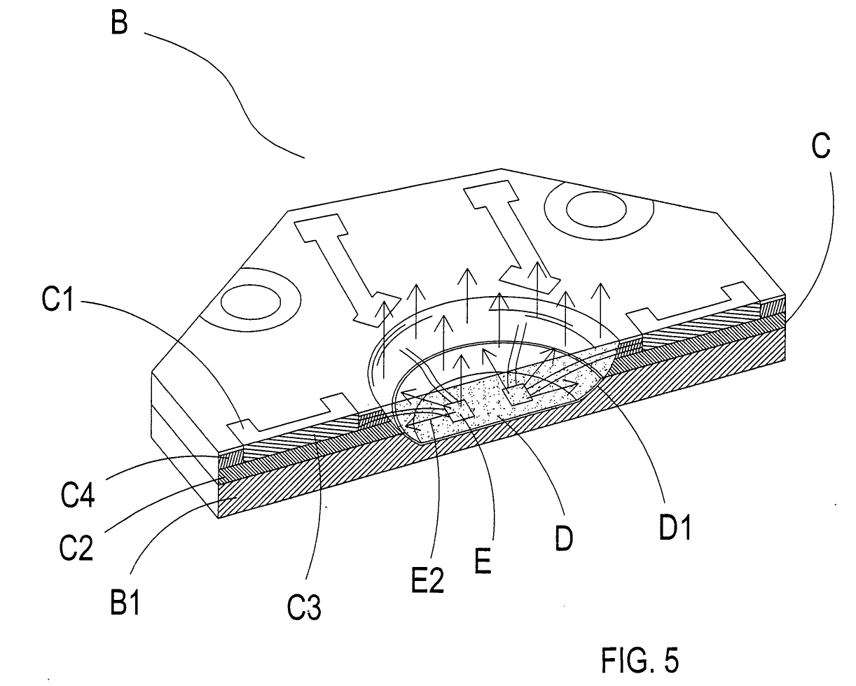

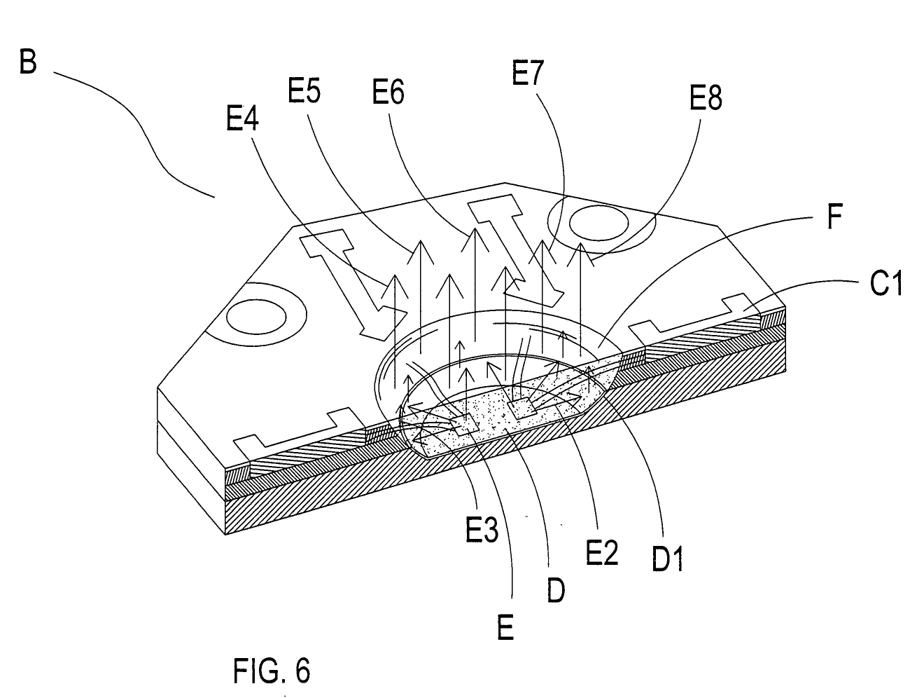

Referring to FIGS. 5 and 6, which show an embodiment of the present invention, wherein, the electrical contacts C1 of the printed circuit C enable the array of the plurality of light-emitting chips E within the concavity D to be respectively connected to the conductive layer C3 of the printed circuit C, and varied high and low electric potential of the printed circuit C enable the array of the plurality of light-emitting chips E to produce multicolor varied frequency spectral light from a single light source. When dissipating heat, the heat dissipating characteristic of the bottom covering heat dissipating layer B1 of the package baseplate B is able to uniformly discharge the light heat energy produced by the varied frequency spectral colored light emitted by the light-emitting chips E from the package baseplate B

Furthermore the high heat dissipation package baseplate B is provided with the heat dissipating layer B1, the insulating layer C2, the conductive layer C3 and the covering layer C4, Moreover the insulating layer C2, the conductive layer C3 and the covering layer C4 make up the printed circuit C of the package baseplate B. The printed circuit C further comprises the electrical contacts C1, which provide for soldering to the array of the plurality of light-emitting chips E within the concavity D.

Furthermore, direct light E2 and diffused light E3 of the light source of the light-emitting chips E disposed within the concavity D of the package baseplate B are transmitted through the light reflecting layer D1 and out an encapsulating compound F of the package baseplate B.

Furthermore, the electrical contacts C1 enable soldering to the array of the plurality of light-emitting chips E. Moreover, the concavity D further comprises one or more than one of the light-emitting chips E, thereby enabling the array of the plurality of light-emitting chips E within the concavity D to emit spectral colored light of varied color temperature by means of the printed circuit C producing varied high and low electric potential.

The light-emitting chips E able to produce varied sources of light further comprise sources of light emitting red light E4, yellow light E5, green light E6, blue light E7, pure white light E8 and related varied frequency spectral light sources. Moreover, the light-emitting chips E can be SMD LEDs (surface mount device light-emitting diodes), LEDs (light-emitting diodes) and related light-emitting devices able to emit varied frequency spectral colored light.

In order to better explicitly disclose advancement and practicability of the present invention, a comparison with prior art is described hereinafter:

Shortcomings of Prior Art

1. The electric current blocking insulating layer spread on the baseplate affects the heat dissipation effect of the package structure.

2. An indirect heat dissipation method between the package structure and chip requires the use of power source connectors to achieve heat dissipation.

3. Shortcoming 2 easily causes reduction in the brightness of the chip, thereby affecting serviceable life of the chip.

4. The soldering layers on the package structure are only able to provide for soldering to a single light-emitting chip.

5. The single soldered light-emitting chip is only able to produce a single frequency spectral light source.

Advantages of the Present Invention

1. When the light-emitting chips E within the concavity D are emitting light, the heat source produced is uniformly discharged directly through the heat dissipating layer B1.

2. Effectively improves brightness of the varied frequency spectral colored light, and extends serviceable life.

3. The electrical contacts C1 of the printed circuit C are respectively connected to the array of the plurality of light-emitting chips E.

4. Control by means of high-low potential enables the light-emitting chips E to produce a light source emitting different colors.

5. The light reflecting layer D1 enables the light-emitting chips E to transmit multicolor varied frequency spectral light from a single light source.

6. Provided with advancement and practicability.

7. Enhances commercial competitiveness.

In conclusion, the present invention in overcoming structural shortcomings of prior art has assuredly achieved effectiveness of anticipated advancement, and, moreover, is easily understood by persons unfamiliar with related art. Furthermore, contents of the present invention have not been publicly disclosed prior to this application, and practicability and advancement of the present invention clearly comply with essential elements as required for a new patent application. Accordingly, a new patent application is proposed herein.

It is of course to be understood that the embodiments described herein are merely illustrative of the principles of the invention and that a wide variety of modifications thereto may be effected by persons skilled in the art without departing from the spirit and scope of the invention as set forth in the following claims.

What is claimed is:

1. A structure for a single light source multicolor LED, comprising a package baseplate having a high heat dissipation effect, the package baseplate is provided with a heat dissipating layer, an insulating layer, a conductive layer and a covering layer; the insulating layer, the conductive layer and the covering layer make up a printed circuit covering a surface of the package baseplate; furthermore, a surface of the package baseplate is provided with a concavity, interior of which is provided with a light reflecting layer and an array of a plurality of light-emitting chips; the present invention is characterized in that extended electrical contacts of the printed circuit enable the array of the plurality of light-emitting chips within the concavity to be respectively soldered to the conductive layer of the printed circuit, and varied high and low electric potential of the printed circuit controls the array of the plurality of light-emitting chips, thereby enabling the package baseplate to produce multicolor varied frequency spectral light from a single light source.

2. The structure for a single light source multicolor LED according to claim 1, wherein the light-emitting chips can be SMD LEDs, LEDs and related light-emitting devices able to emit varied frequency spectral colored light.

3. The structure for a single light source multicolor LED according to claim 1, wherein the light-emitting chips able to produce varied sources of light further comprise sources of light emitting red light, yellow light, green light, blue light, pure white light and related sources of light emitting varied frequency colored light and varied color temperature brightness.

4. The structure for a single light source multicolor LED according to claim 1, wherein the array of the plurality of light-emitting chips within the concavity further comprise one or more than one light-emitting chip, and varied high and low potential produced by the printed circuit effectively controls the array of the plurality of light-emitting chips to emit varied frequency spectral colored light.
